(19) United States
(12) Patent Application Publication
(10) Pub. No.: US 2013/0334685 A1
(43) Pub. Date: Dec. 19, 2013

(54) EMBEDDED PACKAGES AND METHODS OF MANUFACTURING THE SAME

(71) Applicants: Si Han KIM, Yongin-si (KR); Qwan Ho CHUNG, Seoul (KR); Seung Jee KIM, Seongnam-si (KR); Jong Hyun NAM, Seoul (KR); Sang Yong LEE, Icheon-si (KR)

(72) Inventors: Si Han KIM, Yongin-si (KR); Qwan Ho CHUNG, Seoul (KR); Seung Jee KIM, Seongnam-si (KR); Jong Hyun NAM, Seoul (KR); Sang Yong LEE, Icheon-si (KR)

(73) Assignee: SK HYNIX INC., Icheon-si (KR)

(21) Appl. No.: 13/613,479

(22) Filed: Sep. 13, 2012

(30) Foreign Application Priority Data
Jun. 14, 2012 (KR) 10-2012-0063592

(51) Int. Cl. H01L 23/498; H01L 21/56

(52) U.S. Cl. 257/738; 438/126; 257/E23.069; 257/E21.502

(57) ABSTRACT

An embedded package that may be realized by surrounding a semiconductor chip (or a semiconductor die) in a package substrate. A semiconductor chip of an embedded package may be electrically connected to external connection terminals through interconnection wires instead of bumps, and the interconnection wires may be formed using a wire bonding process. A high reliability embedded package results.

### CROSS-REFERENCES TO RELATED APPLICATIONS

The present application claims priority under 35 U.S.C. 119(a) to Korean Application No. 10-2012-0063592, filed on Jun. 14, 2012, in the Korean intellectual property Office, which is incorporated herein by reference in its entirety as set forth in full.

### BACKGROUND

The present invention relates generally to electronic device packages, and more particularly to embedded packages and methods of manufacturing the same.

Electronic devices employed in electronic systems may include various circuit elements such as active elements and/or passive elements. The circuit elements may be integrated in and/or on a semiconductor substrate, thereby constituting the electronic device (also, referred to as a semiconductor chip or a semiconductor die). The electronic device may be mounted on a printed circuit board (PCB) or a package substrate to produce an electronic device package. The package substrate may include circuit interconnections such as silicon interposers. The electronic device package may be mounted on a main board to constitute the electronic systems, for example, computers, mobile systems or data storage media.

Embedded packages have been proposed to reduce the thickness of electronic device packages. The embedded packages may be realized by burying a semiconductor chip (or a semiconductor die) in a package substrate. The embedded packages may employ bumps to electrically connect the semiconductor chip embedded in the package substrate to external connection terminals. The bumps may be electrically connected to the external connection terminals through interconnection lines. Thus, a bonding strength between the bumps and the interconnection lines may affect the reliability of the embedded packages.

### SUMMARY

Example embodiments are directed to embedded packages and methods of manufacturing the same.

According to some embodiments, an embedded package includes a dielectric layer in which a semiconductor chip is buried, an interconnection wire vertically penetrating the dielectric layer to be connected to a contact portion of the semiconductor chip, and an interconnection portion disposed on the dielectric layer and connected to an upper end of the interconnection wire.

In some embodiments, the interconnection wire may include a contact ball portion bonded to the contact portion and a wire stem portion upwardly extending from the contact ball portion to be perpendicular to a top surface of the semiconductor chip.

In some embodiments, the upper end of the interconnection wire may be exposed at a surface of the dielectric layer. The upper end of the interconnection wire is generally distal from the contact ball portion.

In some embodiments, the interconnection portion may include a metal plating layer connected to the upper end of the interconnection wire or a metal foil attached to the upper end of the interconnection wire.

In some embodiments, the dielectric layer may include a base dielectric layer on which the semiconductor chip is put and a surrounding dielectric layer laminated on the base dielectric layer to cover a top surface and sidewalls of the semiconductor chip.

In some embodiments, the embedded package may further include a resist pattern and an external connection terminal. The resist pattern may be disposed on the dielectric layer to cover a portion of the interconnection portion and to expose another portion of the interconnection portion, and the external connection terminal may be disposed on the exposed portion of the interconnection portion.

According to further embodiments, a method of manufacturing an embedded package includes forming interconnection wires that are connected to respective ones of contact portions of a semiconductor chip to be perpendicular to a top surface of the semiconductor chip, forming a surrounding dielectric layer that covers the semiconductor chip and exposes upper ends of the interconnection wires, and forming interconnection portions connected to the upper ends of the interconnection wires on the surrounding dielectric layer.

In some embodiments, forming the interconnection wires may include introducing at least one capillary leading a bonding wire onto a contact portion of a semiconductor chip to bond a contact ball portion to the contact portion, moving up the capillary to form a wire stem portion vertically extending from the contact ball portion, and cutting the bonding wire to separate the bonding wire from the wire stem portion.

In some embodiments, the at least one capillary may include a plurality of capillaries, the plurality of capillaries may be aligned with the corresponding contact portions, and the plurality of capillaries may concurrently operate to simultaneously form the corresponding interconnection wires.

In some embodiments, forming the surrounding dielectric layer may include supplying a dielectric material to encapsulate the semiconductor chip and to cover sidewalls of the wire stem portions supported by the at least one capillary, and forming the surrounding dielectric layer may be followed by cutting the bonding wire.

In some embodiments, forming the surrounding dielectric layer may include providing a dielectric film over the semiconductor chip, and pressurizing the dielectric film such that the interconnection wires penetrate the dielectric film to protrude from a surface of the dielectric film and the semiconductor chip is buried in the dielectric film.

In some embodiments, forming the interconnection portions may include attaching a metal film to the surrounding dielectric layer or plating a metal layer on the surrounding dielectric layer to form an interconnection layer connected to the upper ends of the interconnection wires and patterning the interconnection layer.

In some embodiments, the method may further include polishing the interconnection layer to planarize the interconnection layer before the interconnection layer is patterned.

In some embodiments, the method may further include attaching the semiconductor chip to a base dielectric layer prior to formation of the interconnection wires. In such a case, the surrounding dielectric layer may be laminated on the base dielectric layer to embed the semiconductor chip in the surrounding dielectric layer and the base dielectric layer during formation of the surrounding dielectric layer.

According to further embodiments, a method of manufacturing an embedded package includes disposing a supporting board part over a semiconductor chip, forming interconnection wires that electrically connect contact portions of the semiconductor chip to the supporting board part using a wire bonding process, forming a surrounding dielectric layer that fills an empty space between the semiconductor chip and the supporting board part, separating the interconnection wires from the supporting board part and removing the supporting board part to expose the surrounding dielectric layer, and forming interconnection portions connected to upper ends of the interconnection wires on the exposed surrounding dielectric layer.

In some embodiments, forming the interconnection wires may include introducing at least one capillary leading a bonding wire onto a contact portion of a semiconductor chip to bond a contact ball portion to the contact portion, moving up the capillary to form a wire stem portion vertically extending from the contact ball portion, and stitching an upper portion of the wire stem portion to the supporting board part and cutting the bonding wire to separate the bonding wire from the upper portion of the wire stem portion.

In some embodiments, the supporting board part may include at least one opening through which the at least one capillary moves up and down and through which the wire stem portion passes.

In some embodiments, the method may further include mounting the semiconductor chip on a mold part before the supporting board part is disposed over the semiconductor chip. In such a case, the supporting board part may be combined with the mold part when the supporting board part is disposed over the semiconductor chip.

In some embodiments, the method may further include attaching the semiconductor chip to a base dielectric layer before the semiconductor chip is mounted on the mold part. In such a case, the base dielectric layer with the semiconductor chip may be mounted on the mold part.

In some embodiments, forming the interconnection portions may include attaching a metal film to the surrounding dielectric layer or plating a metal layer on the surrounding dielectric layer to form an interconnection layer connected to the upper ends of the interconnection wires and patterning the interconnection layer.

### BRIEF DESCRIPTION OF THE DRAWINGS

Embodiments of the inventive concept will become more apparent in view of the attached drawings and accompanying detailed description, in which:

FIG. 1 is a cross sectional view illustrating an embedded package according to an embodiment;

FIGS. 2 to 12 are cross sectional views illustrating a method of manufacturing an embedded package according to an embodiment;

FIGS. 13 to 16 are cross sectional views illustrating a method of manufacturing an embedded package according to another embodiment; and

FIGS. 17 to 19 are cross sectional views illustrating a method of manufacturing an embedded package according to yet another embodiment.

### DETAILED DESCRIPTION

Embedded packages according to some example embodiments may be realized by electrically connecting a semiconductor chip embedded in a dielectric layer to interconnection portions disposed on the dielectric layer using a wire bonding process.

It will be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the inventive concepts. As used herein the term “and/or” includes any and all combinations of one or more of the associated listed items.

It will be also understood that when an element is referred to as being located “under”, “beneath,” “below”, “lower,” “on”, “over”, “above,” “upper”, “side” or “aside” another element, it can be directly contact the other element, or at least one intervening element may also be present therebetween. Accordingly, the terms such as “under”, “beneath,” “below”, “lower,” “on”, “over”, “above,” “upper”, “side” “aside” and the like which are used herein are for the purpose of describing particular embodiments only and are not intended to limit the inventive concepts.

In addition, spatially relative terms, such as “beneath,” “below,” “lower,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device (or a package) in use and/or operation in addition to the orientation depicted in the figures. For example, when the device in the figures is turned over, elements described as below and/or beneath other elements or features would then be oriented above the other elements or features. The device may be otherwise oriented (rotated 90 degrees or at other orientations) and the spatially relative descriptors used herein interpreted accordingly.

It will be further understood that the term “semiconductor chip” used herein may correspond to a semiconductor die or a semiconductor substrate including a large scale integrated circuit (LSI), for example, a DRAM circuit or a flash memory circuit. Moreover, it will be understood that the term “contact portion” used herein may correspond to a conductive member for electrical connection, for example, an interconnection pad or a landing pad.

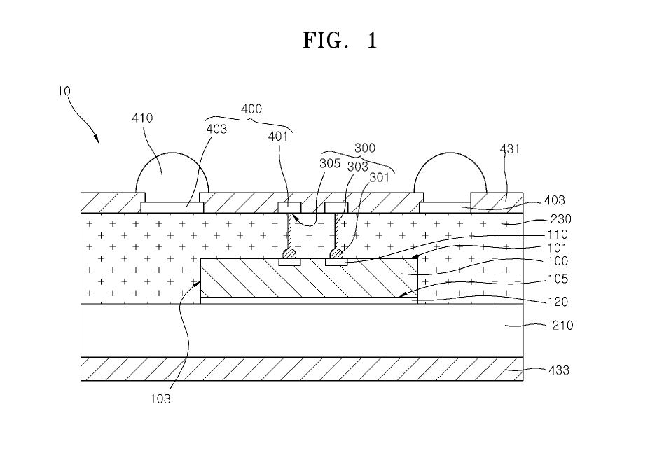

FIG. 1 illustrates an embedded package 10 according to an embodiment that may be configured to include a dielectric layer and a semiconductor chip 100 embedded in the dielectric layer. The dielectric layer may include a base dielectric layer 210 and a surrounding dielectric layer 230. The semiconductor chip 100 may be a memory chip or a logic chip. The memory chip may include a memory circuit such as DRAM circuit or a flash memory circuit, and the logic chip may include a control circuit. Contact portions 110 may be disposed on a top surface 101 of the semiconductor chip 100. The semiconductor chip 100 may be electrically connected to an external device or an external system through the contact portions 110. The contact portions 110 may be chip pads.

The semiconductor chip 100 may include integrated circuits and the integrated circuits may be formed in and/or on active regions of the semiconductor chip 100. When the active regions are located at the top surface 101 of the semiconductor chip 100, the contact portions 110 may be electrically connected to the integrated circuits disposed in and/or on the active regions. In such a case, the contact portions 110 may be electrically connected to the integrated circuits of the semiconductor chip 100 through redistributed lines (not shown). Alternatively, when the integrated circuits are formed in and/or active regions located at a bottom surface 105 of the semiconductor chip 100, the contact portions 110 on the top surface 101 may be electrically connected to the integrated circuits of the semiconductor chip 100 by through-silicon vias (TSVs; not shown) vertically penetrating the semiconductor chip 100.

The semiconductor chip 100 may be mounted on the base dielectric layer 210 such that the bottom surface 105 of the semiconductor chip 100 faces the base dielectric layer 210, and the surrounding dielectric layer 230 may be in contact with or laminated on the base dielectric layer 210 to cover the top surface 101 and sidewalls 103 of the semiconductor chip 100. Thus, the semiconductor chip 100 may be substantially embedded in the dielectric layer including the base dielectric layer 210 and the surrounding dielectric layer 230. The semiconductor chip 100 may be attached to the base dielectric layer 210 using an adhesion layer 120 disposed therebetween. That is, the adhesion layer 120 may be disposed between the semiconductor chip 100 and the base dielectric layer 210.

The base dielectric layer 210 may have a film form and may include an epoxy resin material or a polymer resin material. In some embodiments, the base dielectric layer 210 may be provided in a prepreg form (a pre-impregnated composite material) or a resin clad form. The base dielectric layer 210 may include fillers dispersed therein and/or a reinforcing agent such as glass fiber. The base dielectric layer 210 may be provided to have substantially the same shape as a substrate used in fabrication of a printed circuit board (PCB). For example, the base dielectric layer 210 may include a copper clad laminate (CCL) layer or a resin coated copper (RCC) layer.

Similarly, the surrounding dielectric layer 230 may have a film form and may include an epoxy resin material or a polymer resin material. In some embodiments, the surrounding dielectric layer 230 may be provided in a prepreg form or a resin clad form. The surrounding dielectric layer 230 may also include fillers dispersed therein and/or a reinforcing agent such as glass fiber. The surrounding dielectric layer 230 may include an epoxy molding compound (EMC) material.

The embedded package 10 may further include interconnection wires 300 that vertically penetrate the surrounding dielectric layer 230 to be connected to the contact portions 110. The interconnection wires 300 may be combined with the contact portions 110 using a wire bonding process. Thus, each of the interconnection wires 300 may include a contact ball portion 301 bonded to one of the contact portions 110 and a wire stem portion 303 vertically and upwardly extending from the contact ball portion 301. An upper end 305 of the wire stem portion 303 may be electrically connected to one of interconnection portions 400 disposed on a surface of the surrounding dielectric layer 230 opposite to the base dielectric layer 210.

Each of the interconnection portions 400 may include a first interconnection pattern 401 bonded or connected to the upper end 305 of the wire stem portion 303 and a second interconnection pattern 403 electrically connected to the first interconnection pattern 401. The second interconnection pattern 403 may have a landing pad to which an external connection terminal 410, for example, a solder ball is attached. The external connection terminals 410 may electrically connect the embedded package 10 to an external device or an external system.

A first resist pattern 431 may be disposed on the surrounding dielectric layer 230 to cover the interconnection portions 400, and the first resist pattern 431 may include openings that expose the landing pads of the interconnection portions 410. Thus, the external connection terminals 410 may be electrically connected to the landing pads of the interconnection portions 410 through the openings of the first resist pattern 431. Further, a second resist pattern 433 may be disposed to cover a bottom surface of the base dielectric layer 210 opposite to the semiconductor chip 100. The first and second resist patterns 431 and 433 may include a solder resist material. Bottom interconnection portions (not shown) may be additionally disposed between the base dielectric layer 210 and the second resist pattern 433. Moreover, internal interconnection portions (not shown) may be disposed between the base dielectric layer 210 and the surrounding dielectric layer 230.

According to the present embodiment, the interconnection portions 400 may be electrically connected to the semiconductor chip 100 through the interconnection wires 300 which can be formed using a wire bonding process. No bumps can be employed in the embedded package 10 because the interconnection wires 300 electrically connect the interconnection portions 400 to the contact portions 110 of the semiconductor chip 100. Further, the interconnection portions 400 may be connected to the contact portions 110 through the interconnection wires 300, as described above. Thus, a process for forming through-holes penetrating the dielectric layer, for example, a laser drilling process, may not be required. Accordingly, the manufacturing costs of the embedded packages may be lowered.

In addition, the wire bonding process has been widely known as a high reliability process. That is, when the contact portions 110 of the semiconductor chip 100 are connected to and/or combined with the interconnection portions 400 using the interconnection wires 300 formed by the wire bonding process, a bonding strength between the contact portions 110 and the interconnection portions 400 may be increased to improve the reliability of the embedded package 10.

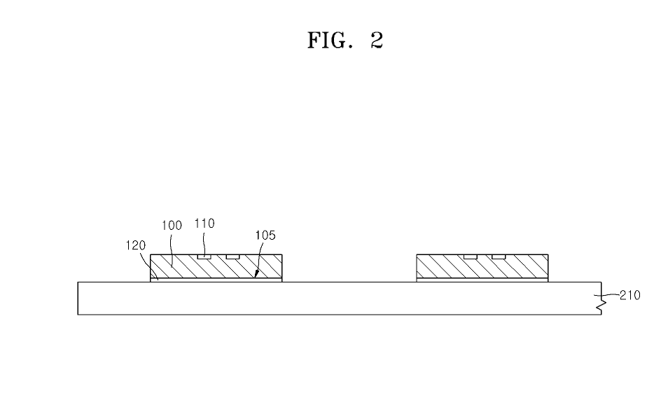

FIG. 2 shows that semiconductor chips 100 having contact portions 110 may be mounted on a base dielectric layer 210 such that the contact portions 110 of the semiconductor chips 100 may be located at an opposite side to the base dielectric layer 210. The semiconductor chips 100 may be mounted on the base dielectric layer 210 by attaching adhesion layers 120 to bottom surfaces 105 of the semiconductor chips 100 and by attaching the adhesion layers 120 to a surface of the base dielectric layer 210. In such a case, the base dielectric layer 210 may act as a carrier substrate for handling the semiconductor chips 100 in subsequent processes. In some embodiments, the semiconductor chips 100 may be attached to another carrier substrate instead of the base dielectric layer 210.

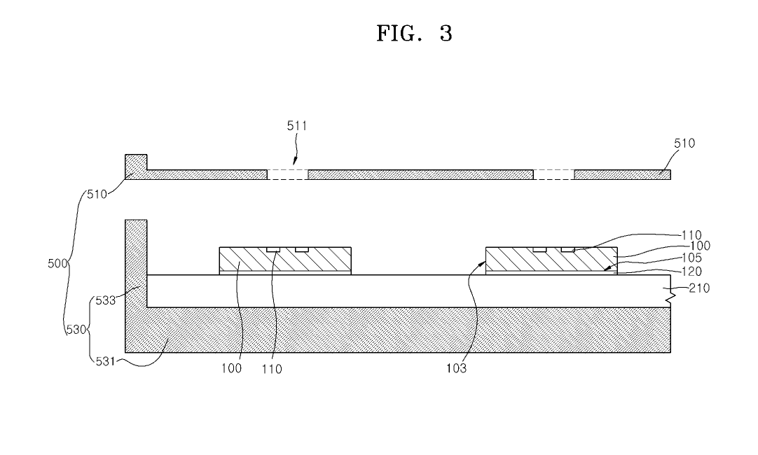

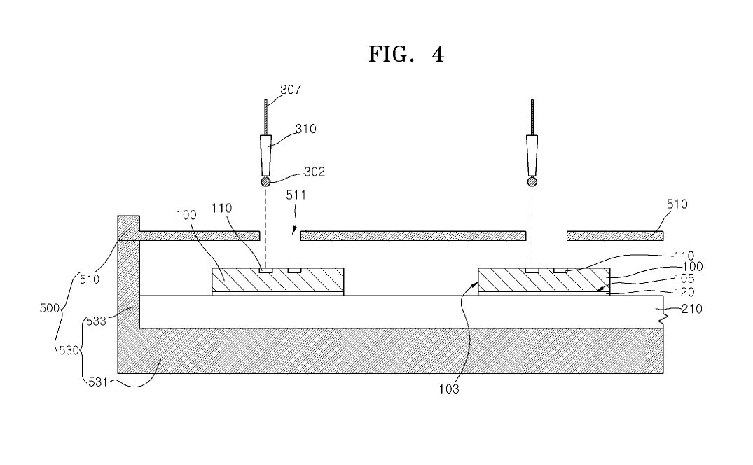

The base dielectric layer 210 to which the semiconductor chips 100 are attached may be put into a molding block 500, as depicted in FIG. 3. The molding block 500 may include a mold part 530 upon which the base dielectric layer 210 is placed, and a supporting board part 510 which is combined with the mold part 530 to cover the semiconductor chips 100 on the base dielectric layer 210. When the base dielectric layer 210 has a panel shape and the semiconductor chips 100 are laterally arrayed and disposed on the base dielectric layer 210, the mold part 530 may be configured to have a recessed region in which the base dielectric layer 210 and the semiconductor chips 100 are inserted. For example, the mold part 530 may include a base portion 531 upon which the base dielectric layer 210 with the semiconductor chips 100 are placed, and a dam portion 533 that upwardly extends from edges of the base portion 531 to surround sidewalls of the base dielectric layer 210 and the semiconductor chips 100. In such a case, the supporting board part 510 may be combined with an upper end of the dam portion 533, as illustrated in FIG. 4. When a dielectric material is provided to cover the base dielectric layer 210 and the semiconductor chips 100 in a subsequent process, the dam portion 533 may act as a barrier that prevents the dielectric material from flowing out of the mold part 530.

The supporting board part 510 may include openings 511 through which a wire bonding process is performed. Further, the supporting board part 510 may act as a bar that limits and/or determines a height or a thickness of a surrounding dielectric layer (230 of FIG. 1) which is formed in a subsequent process. The molding block 500, including the supporting board part 510 and the mold part 530, may function as a frame to determine a shape of the surrounding dielectric layer (230 of FIG. 1) covering the semiconductor chips 100. The openings 511 of the supporting board part 510 may be vertically aligned with the contact portions 110, and a capillary 310 may move up and down through the openings 511 to bond a wire to the contact portions 110 during the wire bonding process. Further, wire stem portions (303 of FIG. 1) formed by the wire bonding process may upwardly extend from the contact portions 110 through the openings 511. The terms “up” and “upwardly” should be interpreted as meaning in a direction substantially away from and generally perpendicular to a top surface 101 of the semiconductor chip 100, as shown in FIG. 1.

Referring again to FIG. 4, after the base dielectric layer 210 with semiconductor chips 100 are placed in the recessed region of the mold part 530, the supporting board part 510 may be combined with the mold part 530 to cover the semiconductor chips 100. The supporting board part 510 may be spaced apart from the semiconductor chips 100. A distance between the supporting board part 510 and the semiconductor chips 100 may be controlled by varying a height of the dam portion 533 or by introducing a combination member into an interface between the supporting board part 510 and the mold part 530. That is, a thickness of a surrounding dielectric layer (230 of FIG. 1) formed in the molding block 500 can be controlled by varying the distance between the supporting board part 510 and the semiconductor chips 100.

A capillary 310 leading a bonding wire 307 may be located over a predetermined one of the openings 511 and may be aligned with any one of the contact portions 110 under the predetermined opening 511. The capillary 310 may be used to form interconnection wires (300 of FIG. 1). The bonding wire 307 may be a gold wire or a copper wire. After the capillary 310 with the bonding wire 307 is located over the predetermined opening 511, an electrical signal may be applied to the capillary 310 to create a spark. As a result, a wire ball 302 may be formed at an end of the bonding wire 307.

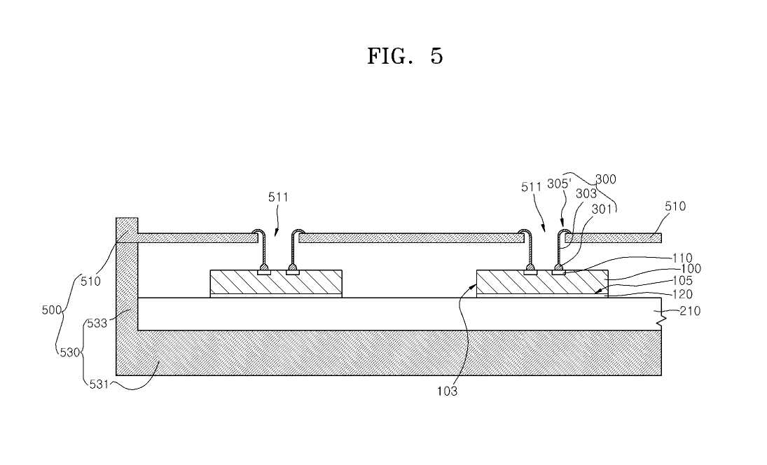

Interconnection wires 300, which electrically connect the contact portions 110 to the supporting board part 510, may be formed using a wire bonding process, as illustrated in FIGS. 4 and 5. Specifically, the capillary 310 located over the opening 511 may move down through the opening 511 such that the wire ball 302 contacts the contact portion 110, and the capillary 310 may be pressurized to form a contact ball portion 301 bonded to the contact portion 110. The capillary 310 may then move up to form a wire stem portion 303 vertically extending from the contact ball portion 301, and an upper portion 305′ of the wire stem portion 303 may be stitched to a portion of the supporting board part 510 adjacent to the opening 511. After the upper portion 305′ of the wire stem portion 303 is stitched to the supporting board part 510, an ultrasonic wave may be applied to the capillary 310 to cut the wire 307. As a result, the bonding wire 307 may be separated from the upper portion 305′ of the wire stem portion 303 bonded to the contact portion 110, thereby forming one of the interconnection wires 300. The aforementioned process steps may be repeatedly performed to form the plurality of interconnection wires 300 combined with respective ones of the contact portions 110.

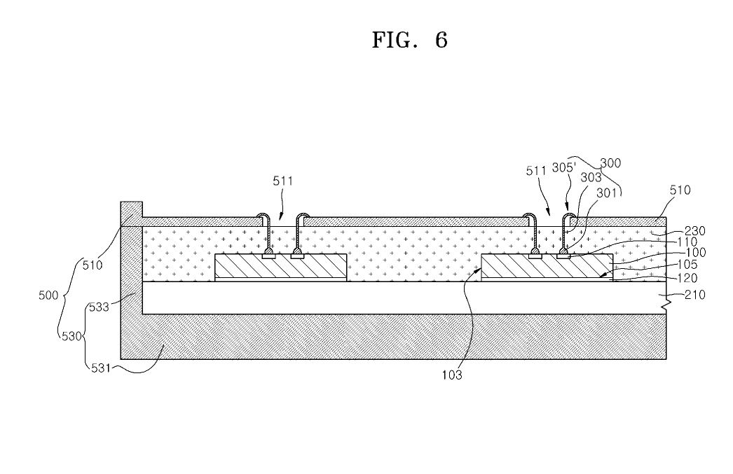

As shown in FIG. 6, a dielectric material or an epoxy molding compound (EMC) material may be injected into an empty space surrounded by the supporting board part 510 and the mold part 530 through the openings 511. Subsequently, the dielectric material or the epoxy molding compound (EMC) material injected into the molding block 500 may be cured using heat, thereby forming a surrounding dielectric layer 230 embedding the semiconductor chips 100. The surrounding dielectric layer 230 may encapsulate the semiconductor chips 100 and may surround the wire stem portions 303. Even though the semiconductor chips 100 and the wire stem portions 303 are embedded in the surrounding dielectric layer 230, the upper portions 305′ of the interconnection wires 300 may be exposed. Since the upper portions 305′ of the interconnection wires 300 are stitched to and combined with the supporting board part 510, the interconnection wires 300 may maintain their initial positions even when the dielectric material or the epoxy molding compound (EMC) material is injected into the molding block 500 and is cured to form the surrounding dielectric layer 230.

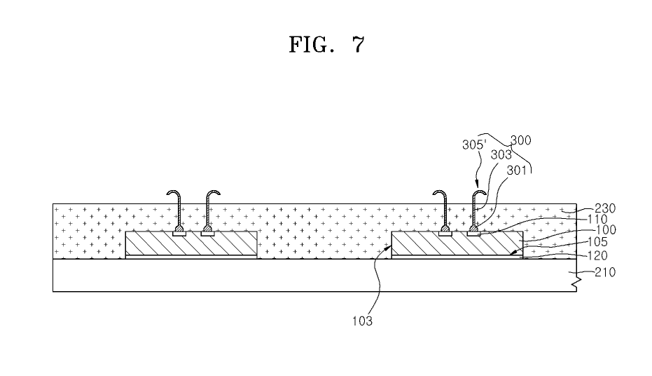

FIG. 7 shows that the molding block 500 may be removed to separate the interconnection wires 300 from the supporting board part 510 of the molding block 500. The molding block 500 may be removed by detaching the supporting board part 510 from the mold part 530 and by detaching the mold part 530 from the base and surrounding dielectric layers 210 and 230. Before the supporting board part 510 is detached from the mold part 530, the upper portions 305′ may be separated from the wire stem portions 303 using a wire cutting process. If the upper portions 305′ are not separated from the wire stem portions 303 before the supporting board part 510 is detached from the mold part 530, the upper portions 305′ may protrude slightly from a top surface of the surrounding dielectric layer 230 after removal of the supporting board part 510.

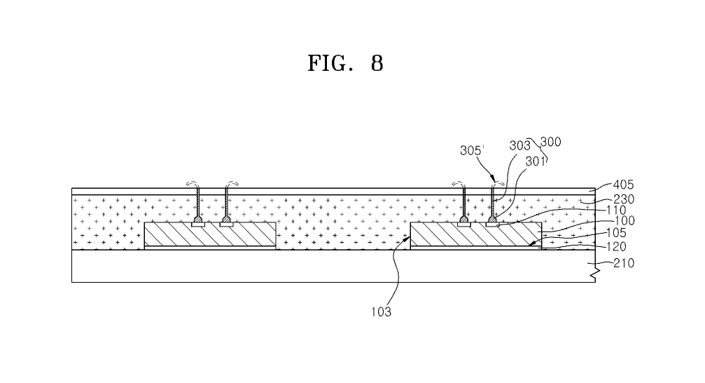

An interconnection layer 405 may be formed on the surrounding dielectric layer 230, as illustrated in FIG. 8. Even after the interconnection layer 405 is formed, the upper portions 305′ may still protrude from a top surface of the interconnection layer 405. The interconnection layer 405 may be formed by growing a metal material such as a copper material using a plating process or by attaching a metal foil such as a copper foil to the surrounding dielectric layer 230. The upper portions 305′ of the interconnection wires 300 may be electrically connected to the interconnection layer 405 because surfaces of the upper portions 305′ are covered with portions of the interconnection layer 405. When the interconnection layer 405 is formed by attaching a metal film to the surrounding dielectric layer 230, a metal plating layer may be additionally formed on the metal film using the metal film as a seed layer. In this case, the additional metal layer and the metal film may constitute the interconnection layer 405.

Subsequently, the interconnection layer 405 may be planarized and polished to improve a surface roughness of the interconnection layer 405. When the upper portions 305′ protrude from the top surface of the interconnection layer 405 opposite to the surrounding dielectric layer 230, the upper portions 305′ may be removed during planarization of the interconnection layer 405. In some embodiments, the upper portions 305′ may be separated from the wire stem portion 303 using an ultrasonic wave applied to the capillary 310 before the interconnection layer 405 is formed, as described above. In such a case, after the interconnection layer 405 is formed, the interconnection wires 300 including the contact ball portions 301 and the wire stem portions 303 may not protrude from the top surface of the interconnection layer 405.

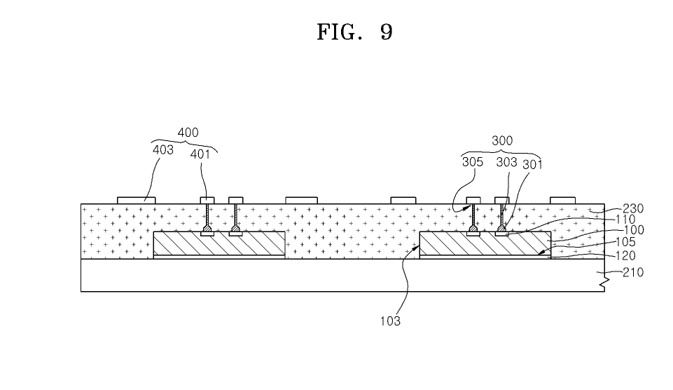

The interconnection layer (405 of FIG. 8) may be patterned to form interconnection portions 400, as shown in FIG. 9. Each of the interconnection portions 400 may be formed to include a first interconnection pattern 401 connected to an upper end 305 of the wire stem portion 303 and a second interconnection pattern 403 electrically connected to the first interconnection pattern 401. The interconnection layer (405 of FIG. 8) may be patterned using a lithography process and an etching process.

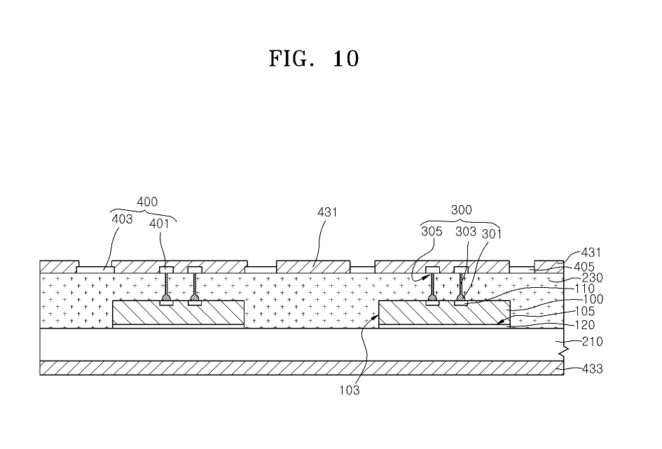

FIG. 10 illustrates a first resist pattern 431 that may be formed on the interconnection portions 400 and the surrounding dielectric layer 230. The first resist pattern 431 may selectively expose the second interconnection patterns 403 of the interconnection portions 400. The first resist pattern 431 may be formed of a solder resist material. Further, a second resist pattern 433 may be formed on a bottom surface of the base dielectric layer 210 opposite to the semiconductor chips 100.

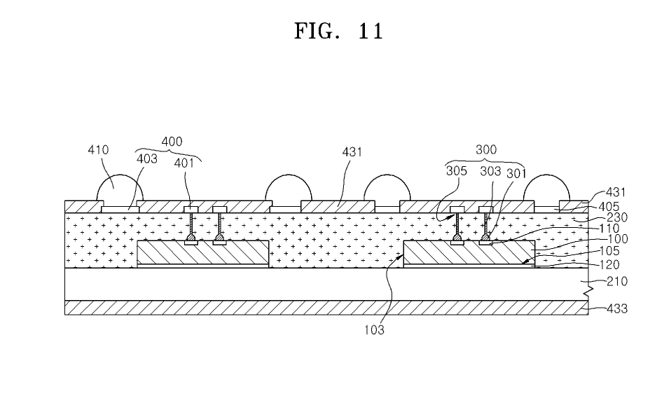

External connection terminals 410, as shown in FIG. 11, may be formed on respective ones of the exposed second interconnection patterns 403 of the interconnection portions 400. The external connection terminals 410 may be solder balls.

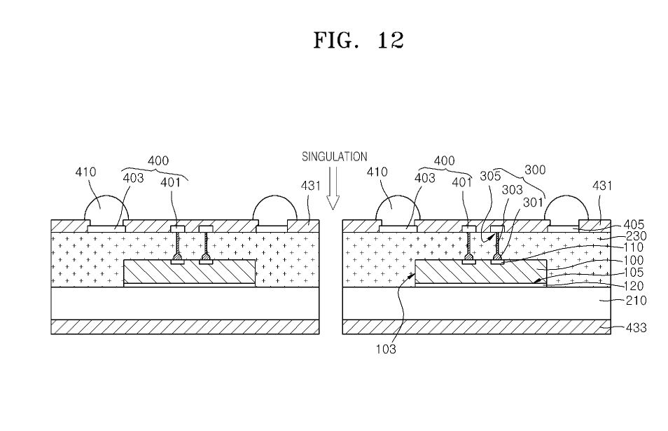

FIG. 12 illustrates that the dielectric layers 210 and 230 between the semiconductor chips 100 may be selectively removed using a singulation process to separate the semiconductor chips 100 from each other. As a result, a discrete embedded package (10 of FIG. 1) may be fabricated.

As described above, the embedded package 10 according to the present embodiment may be fabricated using the molding block 500 including the mold part 530 and the supporting board part 510.

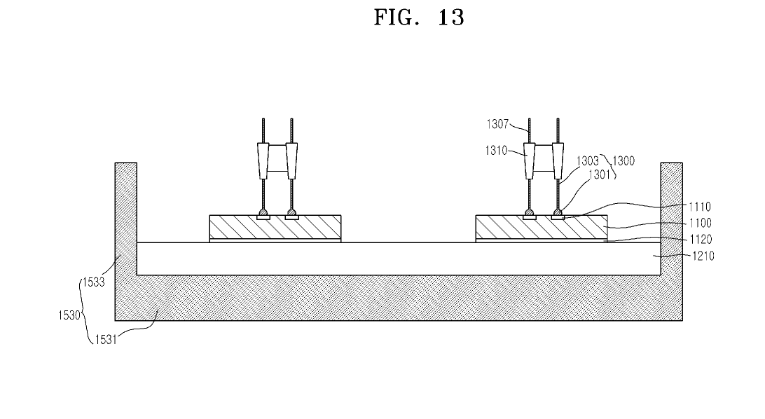

However, the embedded package 10 may be fabricated even without use of the supporting board part 510, as described with reference to FIGS. 13 to 16.

FIG. 13 depicts a base dielectric layer 1210 to which semiconductor chips 1100 are attached that may be mounted on a base portion 1531 of a mold part 1530, as described with reference to FIGS. 2 and 3. The semiconductor chips 1100 may be attached to the base dielectric layer 1210 using an adhesion layer 1120. The mold part 1530 may further include a dam portion 1533 upwardly extending from edges of the base portion 1531 to surround sidewalls of the base dielectric layer 1210 and the semiconductor chips 1100. At least one capillary 1310 leading at least one bonding wire 1307 may be aligned with contact portions 1110 of the semiconductor chips 1100 in a similar manner to that described with reference to FIGS. 4 and 5. If the at least one capillary 1310 includes two or more capillaries, a plurality of interconnection wires 1300 may be simultaneously formed.

Contact ball portions 1301 of the interconnection wires 1300 may be formed on respective ones of the contact portions 1110 using a wire bonding process. The capillaries 1310 may then move up to form wire stem portions 1303 vertically extending from the contact ball portions 1301.

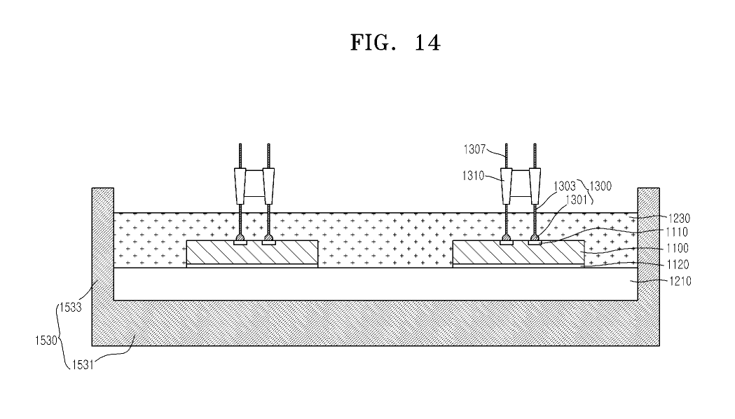

After formation of the wire stem portions 1303, the capillaries 1310 may be fixed to support the wire stem portions 1303 and a dielectric material or an epoxy molding compound (EMC) material may be supplied onto the semiconductor chips 1100 and the base dielectric layer 1210, as shown in FIG. 14. Subsequently, the dielectric material or the epoxy molding compound (EMC) material may be cured using heat, thereby forming a surrounding dielectric layer 1230 encapsulating the semiconductor chips 1100.

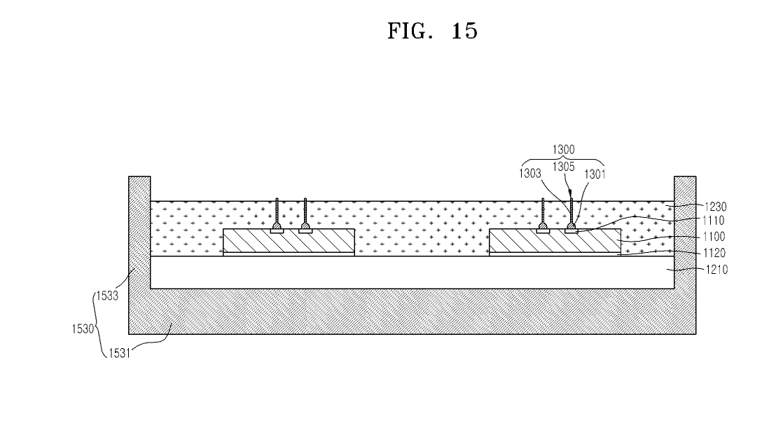

FIG. 15 illustrates that the bonding wires 1307 (FIG. 14) may be cut to separate the bonding wires 1307 from upper ends 1305 of the wire stem portions 1303. The upper ends 1305 of the wire stem portions 1303 may protrude from a top surface of the surrounding dielectric layer 1230. Each of the interconnection wires 1300 may include the contact ball portion 1301, the wire stem portion 1303 and the upper end 1305.

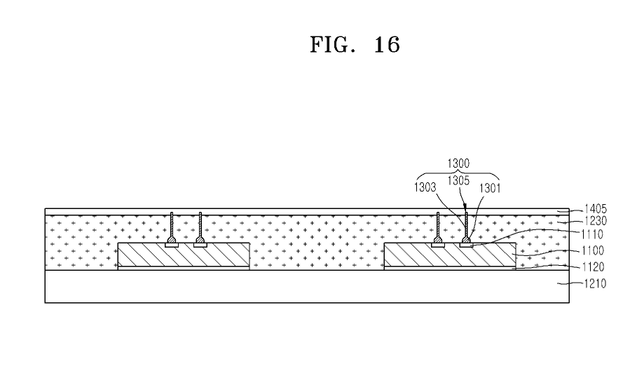

An interconnection layer 1405, as depicted in FIG. 16, may be formed on the surrounding dielectric layer 1230 in the same manner described with reference to FIG. 8. Subsequently, the same process steps as described with reference to FIGS. 9 to 12 may be performed to fabricate embedded packages.

The surrounding dielectric layers 230 and 1230 may be formed in a different fashion from the previous embodiments, as described in the following example embodiment.

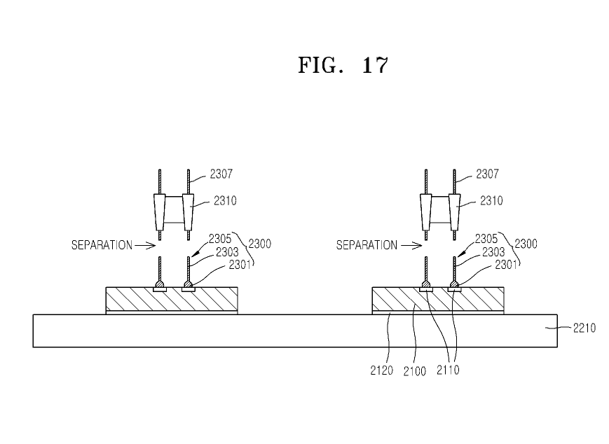

FIG. 17 shows that contact ball portions 2301 of interconnection wires 2300 may be formed on respective ones of contact portions 2110 of semiconductor chips 2100 using at least one capillary 2310 leading a bonding wire 2307. The semiconductor chips 2100 may be attached to a base dielectric layer 2210 using an adhesion layer 2120. The contact ball portions 2301 may be formed in a manner similar to that described with reference to FIGS. 4 and 5 or FIG. 13. Subsequently, the at least one capillary 2310 may move up to form wire stem portions 2303 vertically extending from the contact ball portions 2301, and the bonding wires 2307 may be cut to separate the bonding wires 2307 from upper ends 2305 of the wire stem portions 2303. Accordingly, interconnection wires 2300, which are substantially perpendicular to top surfaces of the semiconductor chips 2100, may be formed. Each of the interconnection wires 2300 may include the contact ball portion 2301, the wire stem portion 2303 and the upper end 2305.

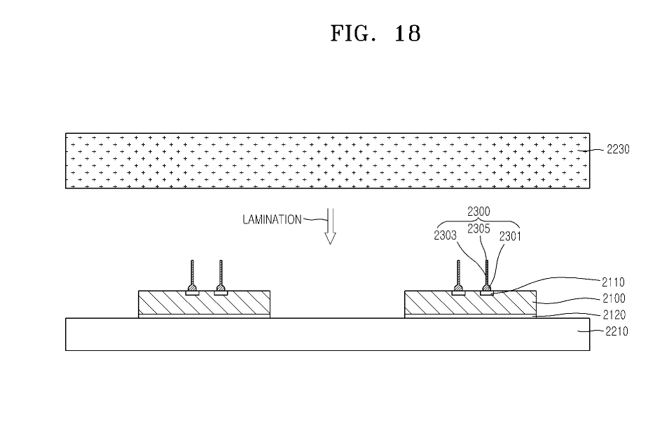

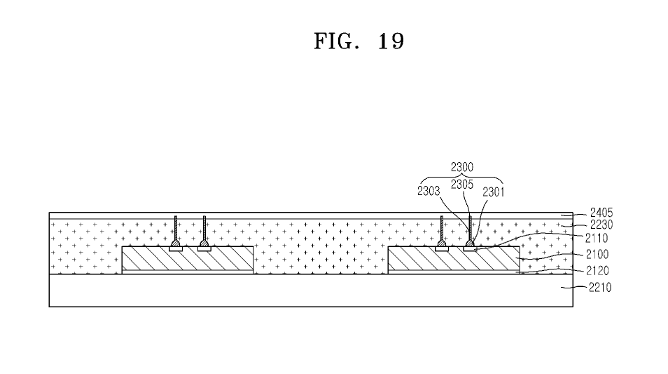

A surrounding dielectric layer 2230 having a film form or a sheet form may be provided over the semiconductor chips 2100 and may be vertically aligned with the semiconductor chips 2100, as shown in FIG. 18. Subsequently, the surrounding dielectric layer 2230 may be pressurized and heated to laminate the surrounding dielectric layer 2230 on the base dielectric layer 2210. As a result, the surrounding dielectric layer 2230 may contact the base dielectric layer 2210 to embed the semiconductor chips 2100 therein. When the surrounding dielectric layer 2230 is laminated on the base dielectric layer 2210, the vertical interconnection wires 2300 may penetrate the surrounding dielectric layer 2230. Thus, the interconnection wires 2300 may be exposed at a top surface of the surrounding dielectric layer 2230 or may protrude from the top surface of the surrounding dielectric layer 2230, as illustrated in FIG. 19. When the surrounding dielectric layer 2230 is laminated on the base dielectric layer 2210, the surrounding dielectric layer 2230 may soften to be flowable because of heat applied thereto. Thus, the vertical interconnection wires 2300 may more readily penetrate the surrounding dielectric layer 2230 without any deformation thereof.

As shown in FIG. 19, an interconnection layer 2405 may be formed in the same manner described with reference to FIG. 8 or 16. Subsequently, the same process steps as described with reference to FIGS. 9 to 12 may be performed to fabricate embedded packages.

According to the embodiments set forth above, a semiconductor chip of an embedded package may be electrically connected to external connection terminals through interconnection wires instead of bumps, and the interconnection wires may be formed using a wire bonding process. Thus, the reliability of the embedded package may be improved.

The example embodiments of the inventive concept have been disclosed above for illustrative purposes. Those skilled in the art will appreciate that various modifications, additions and substitutions are possible, without departing from the scope and spirit of the inventive concept as disclosed in the accompanying claims.

What is claimed is:

1. An embedded package comprising:
a dielectric layer substantially surrounding a semiconductor chip;
an interconnection wire vertically penetrating the dielectric layer to be connected to a contact portion of the semiconductor chip; and
an interconnection portion disposed on the dielectric layer and connected to an upper end of the interconnection wire.

2. The embedded package of claim 1, wherein the interconnection wire comprises a contact ball portion bonded to the contact portion and a wire stem portion upwardly extending from the contact ball portion to be perpendicular to a top surface of the semiconductor chip.

3. The embedded package of claim 1, wherein the upper end of the interconnection wire is exposed at a surface of the dielectric layer.

4. The embedded package of claim 1, wherein the interconnection portion further comprises a conductive portion selected from the group consisting of:
a metal plating layer connected to the upper end of the interconnection wire; and
a metal foil attached to the upper end of the interconnection wire.

5. The embedded package of claim 1, wherein the dielectric layer comprises:
a base dielectric layer on which the semiconductor chip is put; and
a surrounding dielectric layer laminated on the base dielectric layer to cover a top surface and sidewalls of the semiconductor chip.

6. The embedded package of claim 1, further comprising:
a resist pattern disposed on the dielectric layer to cover a portion of the interconnection portion and to expose another portion of the interconnection portion; and
an external connection terminal disposed on the exposed portion of the interconnection portion.

7. A method of manufacturing an embedded package, the method comprising the steps of:
forming interconnection wires that are connected to respective ones of contact portions of a semiconductor chip to be substantially perpendicular to a top surface of the semiconductor chip;
forming a surrounding dielectric layer that covers the semiconductor chip and exposes upper ends of the interconnection wires; and
forming interconnection portions connected to the upper ends of the interconnection wires on the surrounding dielectric layer.

8. The method in accordance with claim 7, wherein the step of forming interconnection wires further comprises the steps of:
introducing at least one capillary leading a bonding wire onto a contact portion of a semiconductor chip to bond a contact ball portion to the contact portion;
moving up the capillary to form a wire stem portion vertically extending from the contact ball portion; and
cutting the bonding wire to separate the bonding wire from the wire stem portion.

9. The method in accordance with claim 8:
wherein the at least one capillary includes a plurality of capillaries;
wherein the plurality of capillaries are aligned with the corresponding contact portions; and
wherein the plurality of capillaries concurrently operate to simultaneously form the corresponding interconnection wires.

10. The method in accordance with claim 8, wherein the step of forming the surrounding dielectric layer further comprises the step of:
supplying a dielectric material to encapsulate the semiconductor chip and to cover sidewalls of the wire stem portions supported by the at least one capillary; and
wherein the step of forming the surrounding dielectric layer is followed by the step of cutting the bonding wire.

11. The method in accordance with claim 7, wherein the step of forming the surrounding dielectric layer further comprises the steps of:
providing a dielectric film over the semiconductor chip; and
pressurizing the dielectric film such that the interconnection wires penetrate the dielectric film to protrude from a surface of the dielectric film and the semiconductor chip is substantially surrounded by the dielectric film.

12. The method in accordance with claim 7, wherein the step of forming the interconnection portions further comprises the steps of:
associating a conductive portion with the surrounding dielectric layer using a process selected from the group consisting of:
attaching a metal film to the surrounding dielectric layer; and
plating a metal layer on the surrounding dielectric layer;
such that an interconnection layer is formed that is connected to the upper ends of the interconnection wires; and
patterning the interconnection layer.

13. The method in accordance with claim 12, further comprising the step of polishing the interconnection layer to planarize the interconnection layer before the interconnection layer is patterned.

14. The method in accordance with claim 7, further comprising the step of attaching the semiconductor chip to a base dielectric layer prior to formation of the interconnection wires;
wherein the surrounding dielectric layer is laminated on the base dielectric layer to embed the semiconductor chip in the surrounding dielectric layer and the base dielectric layer during formation of the surrounding dielectric layer.

15. A method of manufacturing an embedded package, the method comprising the steps of:
disposing a supporting board part over a semiconductor chip;
forming interconnection wires that electrically connect contact portions of the semiconductor chip to the supporting board part using a wire bonding process;
forming a surrounding dielectric layer that fills an empty space between the semiconductor chip and the supporting board part;
separating the interconnection wires from the supporting board part and removing the supporting board part to expose the surrounding dielectric layer; and
forming interconnection portions connected to upper ends of the interconnection wires on the exposed surrounding dielectric layer.

16. The method in accordance with claim 15, wherein the step of forming the interconnection wires further comprises the steps of:
introducing at least one capillary leading a bonding wire onto a contact portion of a semiconductor chip to bond a contact ball portion to the contact portion;
moving up the capillary to form a wire stem portion vertically extending from the contact ball portion; and
stitching an upper portion of the wire stem portion to the supporting board part and cutting the bonding wire to separate the bonding wire from the upper portion of the wire stem portion.

17. The method in accordance with claim 16, wherein the supporting board part includes at least one opening through which the at least one capillary moves up and down and through which the wire stem portion passes.

18. The method in accordance with claim 15, further comprising the step of mounting the semiconductor chip on a mold part before the supporting board part is disposed over the semiconductor chip;
wherein the supporting board part is combined with the mold part when the supporting board part is disposed over the semiconductor chip.

19. The method in accordance with claim 18, further comprising the step of attaching the semiconductor chip to a base dielectric layer before the semiconductor chip is mounted on the mold part;
wherein the base dielectric layer with the semiconductor chip is mounted on the mold part.

20. The method in accordance with claim 15, wherein the step of forming the interconnection portions further comprises the steps of:
associating a conductive portion with the surrounding dielectric layer using a process selected from the group consisting of:
attaching a metal film to the surrounding dielectric layer; and
plating a metal layer on the surrounding dielectric layer;
such that an interconnection layer is formed that is connected to the upper ends of the interconnection wires; and
patterning the interconnection layer.
